(19) United States
(12) Patent Application Publication
(10) Pub. No.: US 2003/0166323 A1
(43) Pub. Date: Sep. 4, 2003

(54) RAISED EXTENSION STRUCTURE FOR HIGH PERFORMANCE CMOS

(75) Inventors: Dirk Vietzke, Fishkill, NY (US); Thomas Schafbauer, Wappinger Falls, NY (US); James Brighten, Hopewell Junction, NY (US); Birgit Von Ehrenwall, Dresden (DE)

Correspondence Address: Law Offices of Jerome J. Norris, Suite 305, 1901 Pennsylvania Avene, N.W., Washington, DC, 20006, US

(73) Assignee: Infineon Technologies North America Corp.

(21) Appl. No.: 10/085,055

(22) Filed: Mar. 1, 2002

(51) Int. Cl. H01L 21/8238; H01L 21/336

(52) U.S. Cl. 438/299; 438/300

(57) ABSTRACT

In a process of fabricating on a substrate a CMOS semiconductor device having a gate electrode, a raised source, and a raised drain, the improvement comprising further incorporating a raised extension, comprising:

providing a silicon surface on an insulator layer;

proving a gate adjacent to an intended source/drain region;

providing an offset spacer adjacent to the gate;

growing a source/drain region by selective epitaxy;

forming an extension with one or more dopants by ion implantation; and

forming a hdd spacer.

### BACKGROUND OF THE INVENTION

1. Field of Invention

The invention generally relates to semiconductor devices, and more particularly, complementary metal oxide semiconductors (CMOS) devices of improved contact resistance as a result of not only raising the s/d sheet resistance by raising the s/d area, but also raising the extension area to provide an additional reduction of the extension resistance and an increase of the on-current.

2. Description of the Related Art

It is known that metal oxide semiconductors (MOS) are used in high density integrated circuits, in large measure because processing procedures provide high packing densities. In the fabrication of these MOS transistors, heavily doped source and drain electrodes are used to reduce parasitic resistance in the device. However, these doping impurities implanted into the source and drain electrodes tend to diffuse into the junction areas that underlie the source/drain (s/d) and gate electrode to increase the junction area depth. Junction areas of large depths are known to create two related problems, namely, increased junction leakage current and channel punch-through current. This condition is referred to as the short channel effect and requires an increased channel length between source and drain electrodes.

Raised s/d electrodes have been used in MOS transistors, partially for solving the problems of gate electrode size and source/drain junction depth In this connection, it is known that source and drain electrodes are in the same horizontal plane as the gate electrode due to the fact that all three electrodes are deposited on the substrate. Shallower source/drain junction areas provide more widely separated source/drain space charge regions, thereby minimizing susceptibility of the transistor to leakage current between junction areas.

A process for forming raised source/drain electrodes is to deposit epitaxial silicon on the s/d area of the substrate—due to the fact that when silicon is deposited, or grown on the substrate, it tends to take on the crystalline structure of the underlying silicon substrate. Nevertheless, the profile thickness of these epitaxial layers tend not to be uniform. That is, the epitaxial layer tends to be thickest in its center with decreasing thickness towards the edge. Further, during deposition of an epitaxial layer on a substrate adjacent to a gate electrode, an area of minimum silicon thickness occurs at the source or drain electrode where it intersects the sidewalls of the gate electrodes. The area of minimum thickness is known as the epitaxial silicon notch (epi notch), sometimes referred to “the notch”.

Following ion implantation into the s/d electrodes, diffusion of doping impurities into the junction areas tends to be greater in regions underlying the epitaxial notches. This makes the junction area or depth thickness greater in the region underlying the notch than in the region underlying the center of the epitaxial silicon area. Putting it differently, doping impurities migrate through the epitaxial notch far easier than through the center of the epitaxial layer, thereby causing non-uniform junction thicknesses. The areas of deeper junction depth between the gate electrode and the s/d electrodes essentially defines or locates the s/d charge regions to induce the flow of leakage current. Therefore, building a raised s/d MOS transistor with non-uniform junctions areas near the gate yields many of the same leakage problems that this fabrication technique was designed to prevent.

Augendre et al, Elevated Source Drain by Sacrificial Selective Epitaxy for High Performance Deep Submicron CMOS: Process Window Versus Complexity, Electron Devices, IEEE Transactions on, Volume: 47 Issue: Jul. 7, 2000 Page(s): 1484-1491, disclose a method of obtaining cost reduction and performance improvement on downscaled CMOS devices by the use of elevated source/drain architecture. The CMOS technology is scaled down to 0.18 micron and features S/D made with sacrificial selective epitaxy. The epitaxy is done after junction formation to provide the increased process window. The S/D process leads to dc and rf device performance enhancements.

U.S. Pat. No. 5,677,214 disclose a raised source/drain MOS transistor with covered epitaxial notches and a method of preparing the same. The method entails:

a) forming a gate, including gate insulation overlying the substrate, and a gate electrode overlying the gate insulation;

b) forming insulating sidewalls on opposite sides of the gate electrode;

c) forming a layer of epitaxial polycrystalline silicon over the substrate to form epitaxial polycrystalline silicon regions on opposite sides of the gate electrode, each epitaxial polycrystalline silicon region having a maximum central thickness transistioning to a thinner edge thickness, an edge of each epitaxial polycrystalline silicon region being adjacent the gate such that the edge forms a notch of thin epitaxial polycrystalline silicon adjacent the gate;

d) extending the gate insulating sidewalls, initially formed in step b), to form thick sidewalls which cover the epitaxial notches formed in step c); and

e) implanting doping impurities into each epitaxial polycrystalline silicon region formed in step c) to form source and drain electrodes, whereby the implantation of doping impurities through the epitaxial notches is masked by the thick gate insulating sidewalls formed in step d).

A method of forming an MOS transistor having raised source and drain regions is disclosed in U.S. Pat. No. 6,150,244. The method comprises:

forming a plurality of isolation regions on the substrate to isolate a plurality of active regions;

forming sequentially a first dielectric layer, a first conductor layer and a second dielectric layer on the substrate;

forming on one of the active regions a patterned first resist layer to mask a portion of the second dielectric layer and the underlying first conductor layer and first dielectric layer;

removing the second dielectric layer, the first conductor layer and the first dielectric layer other than the portion masked by the first resist layer to form the gate electrode structure;

depositing sequentially a third dielectric layer and a fourth dielectric layer on the substrate and the gate electrode structure;

removing a top portion of the fourth dielectric layer to expose a portion of the third dielectric layer covering the gate electrode structure;

forming on the substrate a patterned second resist layer to mask portions of the fourth dielectric layer;

removing the fourth dielectric layer other than the portions masked by the second resist layer to form a plurality of trenches adjacent to the gate electrode structure, wherein portions of the substrate are exposed, and wherein spacers are formed on sidewalls of the gate electrode structure at the same time;

filling the plurality of trenches with a second conductor layer;

doping the second conductor layer in the trenches with dopants; and

driving the dopants into the substrate underneath the trenches to form the raised source and the raised drain.

U.S. Pat. No. 6,228,729 B1 disclose MOS transistors having raised source and drain and interconnects. The process comprises:

forming sequentially a first dielectric layer and a first conductor layer on the substrate;

forming one or more inset isolation regions in the substrate by removing portions of the first conductor layer, the first dielectric layer and the substrate underlying the first dielectric layer;

filling each the inset isolation region with an isolation layer;

forming a second dielectric layer on top of the first conductor layer and the isolation layers;

simultaneously forming a first trench by removing a portion of each of the second dielectric layer, the first conductor layer, the first dielectric layer and the substrate underlying the first dielectric layer and forming a second trench by removing a portion of the isolation layer;

forming a plurality of cavities at the bottom of the first trench by laterally removing portions of the first dielectric layer;

filling each the cavity with a second conductor layer;

forming a plurality of dielectric sidewalls and a dielectric bottom layer in the first trench;

forming the gate electrode and the interconnect by filling the first trench and the second trench with a third conductor layer;

doping the first conductor layer with dopants; and

forming the raised source and the raised drain by driving the dopants into the substrate.

In the case of complementary metal-oxide semiconductors (CMOS), which are devices consisting of two complementary MOSFET's (one n-channel and one p-channel type) integrated into a single chip, it is known that contact resistance as well as the s/d sheet resistance can be improved by raising the s/d area, by selective epitaxial growth of silicon or silicon/germanium after forming the spacer and before implanting the Heavily Doped Drain (HDD).

Since newer technologies associated with preparation of CMOS devices cause these devices to suffer from decreased junction depth and decreased thermal budget (increased sheet resistance), there is a need to provide a method of preparing CMOS devices to alleviate or lessen these disadvantages.

### SUMMARY OF THE INVENTION

One object of the present invention is to provide CMOS devices having raised s/d areas, but characterized by less decreased junction depth than in the case of a CMOS with raised s/d per se, by also raising the extension area.

Another object of the present invention is to provide CMOS devices having raised s/d areas, but less encumbered by decreased thermal budget (increased sheet resistance) than in the case of a CMOS with raised s/d areas per se, by also raising the extension area.

A further object of the present invention is to provide CMOS devices having raised s/d areas, but characterized by additional reductions in the extension resistance than in the case of a CMOS with raised s/d areas per se, by also raising the extension area.

A further object yet still of the present invention is to provide CMOS devices having raised s/d areas, but characterized by an increase in the on-current that is greater than the increase attributed to a CMOS with raised s/d areas per se, by also raising the extension area.

### BRIEF DESCRIPTION OF THE DRAWING FIGURES

FIG. 1 depicts a CMOS device of the prior art having a raised s/d area.

FIG. 2 depicts a CMOS device of the present invention having a raised s/d area and a raised extension.

FIG. 3 is a graph showing a trade-off curve between a raised extension structure and a raised s/d structure to gain the benefit of improved extension as well as s/d resistance, but without speed degradation of an increasing coverlap.

### DETAILED DESCRIPTION OF PREFERRED EMBODIMENT OF THE INVENTION

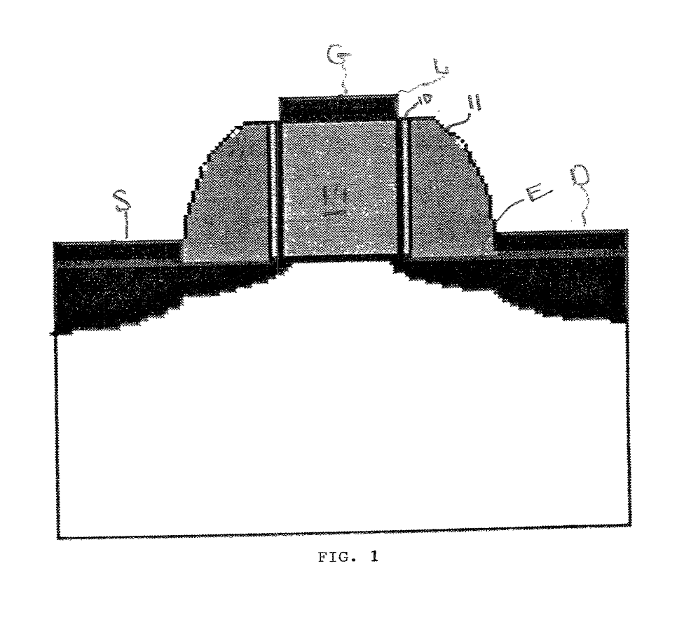

Reference is now made to FIG. 1 which depicts a CMOS device of the prior art having a raised s/d area. In this figure, the raised source and drain areas are designated, respectively by S and D. The gate electrode is designated by G. In general, preparation of this raised s/d CMOS structure entails the simplified process flow of:

a) preparing a PC stack;

b) forming an offset spacer from the stack;

c) forming an extension by ion implantation;

d) forming sidewall spacers; and

e) forming raised source drain regions by selective epitaxy.

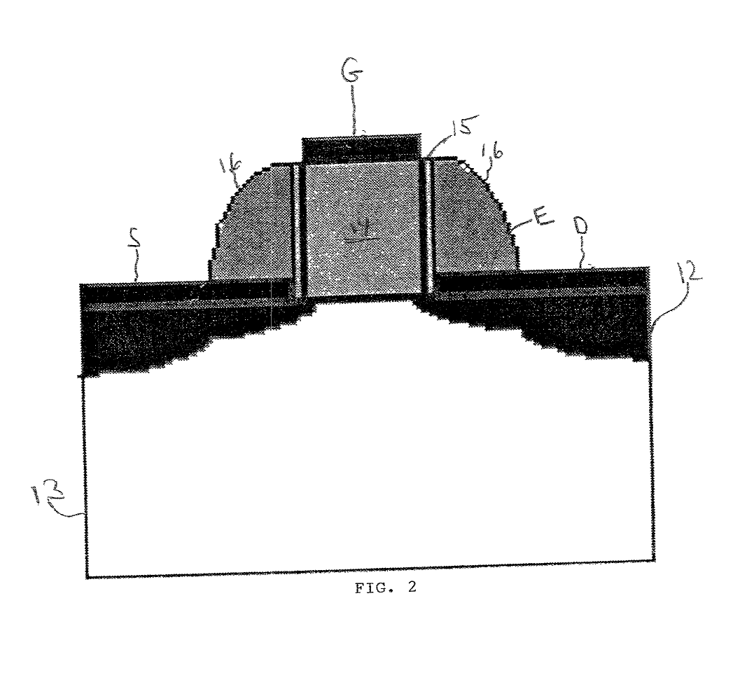

FIG. 2 depicts the raised extension CMOS device of the invention, which results in an additional reduction of the extension resistance and an increase of the on-current. This structure, in general, is formed by the simplified process flow of:

a) forming a PC stack;

b) forming an offset spacer from the stack;

c) forming a selective epitaxial layer on the s/d region;

d) forming an extension by ion implantation; and

e) forming sidewall spacers.

A comparison of the method of forming a CMOS structure with raised s/d and with a raised extension are as follows:

| Raised s/d | Raised Extension |
|---|---|
| PC stack | PC stack |
| offset spacer | offset spacer |
| extension implant | selective epi |
| spacer | extension implant |
| selective epi | spacer |

The disadvantage of raising the extension is an increased overlap capacitance. However, Table I shows a comparative basis for the advantage obtained by the raised extension over the raised s/d.

TABLE I

| | Raised extension | Raised s/d |
|---|---|---|
| Improved contact | YES | YES |
| resistance | | |
| Improved s/d | YES | YES |
| resistance | | |
| Improved ext. | YES | NO |
| resistance | | |
| Increased Cov | YES | NO |

The disadvantage of the increased overlap is reflected in simulation results used to evaluate the potential of the raised extension structure. If the extension is raised by 20 nm the on-current is improved by about 7%, but the ring oscillator speed becomes 18% worse. A three-times thicker extension spacer (4 nm to 12 nm) leads to the same on-current improvement, but worsens the ring oscillator speed by only 5%.

The invention CMOS structure is a trade-off between both structures to gain the benefit of improved extension resistance as well as s/d resistance, but without the speed degradation of an increasing overlap. Therefore, the “ideal” structure is a graduated epitaxial layer starting at the extension spacer and going over in a raised s/d structure (FIG. 2). The advantage is the optimal spreading resistance in the extension layer for the current arriving from the channel region without changing the overlap capacitance too much, since the vertically overlapping area of epi and polygate is very small.

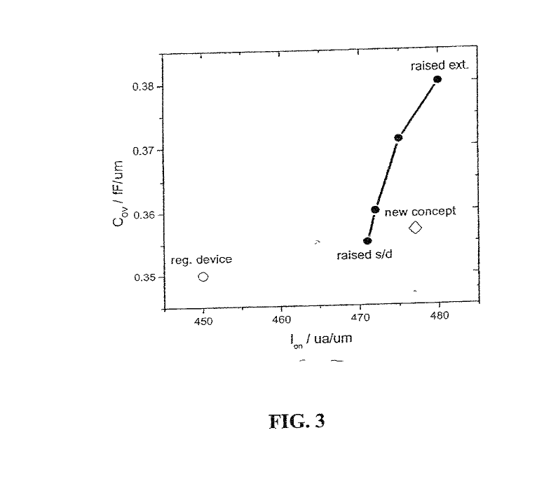

TCAD simulations show a 4% increase of the on-current at almost the same overlap capacitance. It is therefore seen that the 4% current increase goes directly over in a performance increase of the ring oscillator, as shown in the trade-off curve of the graph of FIG. 3.

More specifically with regard to FIG. 1, there may be a liner L covering the gate, surrounded by an inner thinner spacer 10. An extension implant E is affected to provide a buffer layer in the s/d extension design and, if need be, to protect the gate from damage if the outer spacer 11 is removed. Selective epitaxy (epi), preferably silicon epitaxy, is then employed to raise the s/d regions.

Details in regard to preparation of the invention CMOS structure of FIG. 2 entail:

providing a silicon surface 12 on an insulator layer 13, and forming a PC stack, gate stack or gate 14 and an inner thinner or offset spacer 15; employing selective epitaxy (epi) to raise the s/d regions, utilizing an extension implant E to provide a buffer layer in the s/d extension design; and forming a raised extension area 16 by ion implantation.

The improved raised extension structure for high performance CMOS devices of the invention may be obtained by process integration in three basic ways:

1. Disposable Spacer

PC etch

extension spacer (oxide) about 100 A

extension implant

disposable oxide spacer (nitride)

epitaxial growth of 20 nm-40 nm silicon or silicon/germainium layer

etch of disposable spacer

epitaxial growth of a thinner silicon or silicon germanium layer (5 nm-10 nm)

hdd spacer nitride

2. Overetched Oxide Spacer

PC etch

extension spacer (oxide) less than 100 A

extension implants

deposit oxide (less than 100 A)

deposit nitride (300 A-400 A)

etch nitride

overetch of oxide so that it is almost gone under the nitride

epitaxial growth of 20 nm-40 nm silicon/germanium with reduced material transport under the nitride to get a ramp in the epilayer

etch nitride

hdd spacer

3. Different Growth Rates by Implant

(to get different growth rates on silicon by applying damage to the surface under hdd)

PC etch

disposable oxide spacer

damage implant e.g. Germanium

etch spacer

epitaxial growth of 20 nm-40 nm silicon/germanium with a higher rate of hdd area since there is a surface damage

extension implants

spacer upon evaluation, process 3 is simpler than 1 and 2.

We claim:

1. In a process of fabricating on a substrate a CMOS semiconductor device having a gate electrode, a raised source, and a raised drain, the improvement comprising further incorporating a raised extension, comprising:
providing a silicon surface on an insulator layer;
proving a gate adjacent to an intended source/drain region;
providing an offset spacer adjacent to said gate;
growing a source/drain region by selective epitaxy;
forming an extension with one or more dopants by ion implantation; and
forming a hdd spacer.

2. The process of claim 1 wherein one or more dopants is selected from the group consisting of arsenic, phosphorous, boron and boron diflouride.

3. The process of claim 2 wherein said dopant is arsenic.

4. The process of claim 2 wherein said dopant is phosphorous.

5. The process of claim 2 wherein said dopant is boron.

6. The process of claim 2 wherein said dopant is boron diflouride.

7. The process of claim 3 wherein growth by selective epitaxy is accomplished using silicon.

8. The process of claim 3 wherein growth by selective epitaxy is accomplished using silicon/germanium.

9. The process of claim 4 wherein growth by selective epitaxy is accomplished using silicon.

10. The process of claim 4 wherein growth by selective epitaxy is accomplished using silicon/germanium.

11. The process of claim 5 wherein growth by selective epitaxy is accomplished using silicon.

12. The process of claim 5 wherein growth by selective epitaxy is accomplished using silicon/germanium.

13. The process of claim 6 wherein growth by selective epitaxy is accomplished using silicon.

14. The process of claim 6 wherein growth by selective epitaxy is accomplished using silicon/germanium.
